(19) United States
(12) Patent Application Publication
(10) Pub. No.: US 2025/0175099 A1
(43) Pub. Date: May 29, 2025

(54) PHOTOELECTRIC-THERMOELECTRIC-PIEZOELECTRIC COUPLED HYBRID ENERGY HARVESTING APPARATUS

(71) Applicant: BEIJING INSTITUTE OF TECHNOLOGY, Beijing (CN)

(72) Inventors: Fang DENG, Beijing (CN); Ning DING, Beijing (CN); Xiangyang WANG, Beijing (CN); Yeyun CAI, Beijing (CN); Hailing FU, Beijing (CN); Bowei XIE, Beijing (CN); Maobin LV, Beijing (CN); Jiadong ZHOU, Beijing (CN); Qi CHEN, Beijing (CN); Chen CHEN, Beijing (CN)

(73) Assignee: BEIJING INSTITUTE OF TECHNOLOGY, Beijing (CN)

(21) Appl. No.: 18/900,966

(22) Filed: Sep. 30, 2024

(30) Foreign Application Priority Data
Nov. 24, 2023 (CN) 202311582154.1

(51) Int. Cl. H02N 2/18; H02S 10/30; H10N 10/10

(52) U.S. Cl. CPC H02N 2/186; H02S 10/30; H10N 10/10

(57) ABSTRACT

A photoelectric-thermoelectric-piezoelectric coupled hybrid energy harvesting apparatus includes a housing, a photoelectric-thermoelectric energy harvesting apparatus, and a piezoelectric energy harvesting apparatus. The housing is configured to support and accommodate the photoelectric-thermoelectric energy harvesting apparatus, the piezoelectric energy harvesting apparatus, and a heat dissipation plate. The photoelectric-thermoelectric energy harvesting apparatus is respectively arranged on five surfaces of the housing to implement reciprocally coupled harvesting of solar energy and thermal energy in a working environment. The piezoelectric energy harvesting apparatus is arranged on a right side surface of an interior of the housing to implement reciprocally coupled harvesting of thermal energy and mechanical energy in the working environment. With the use of the photoelectric-thermoelectric-piezoelectric coupled hybrid energy harvesting apparatus, reciprocal harvesting of solar energy, thermal energy, and mechanical energy that widely exist in nature can be realized, thereby breaking through the simple “1+1” implementation mode of multi-source energy harvesting.

### CROSS REFERENCE TO THE RELATED APPLICATIONS

This application is based upon and claims priority to Chinese Patent Application No. 202311582154.1, filed on Nov. 24, 2023, the entire contents of which are incorporated herein by reference.

### TECHNICAL FIELD

The present disclosure relates to a photoelectric-thermoelectric-piezoelectric coupled hybrid energy harvesting apparatus, and belongs to the field of electrical power generation, electrical transformation, or power distribution in electrical engineering.

### BACKGROUND

With the development of the Internet of Things technology, smart terminals are widely deployed in various indoor, outdoor, mobile, and static scenarios such as smart homes, intelligent transportation, and digital factories. To meet common requirements of Internet of Things wireless intelligent terminals for long-term, autonomous, and sustainable operation, multi-source ubiquitous energy harvesting technologies using photoelectric, thermoelectric, and piezoelectric energy harvesting mechanisms provide an effective and sustainable energy supply solution for self-powered operation of the intelligent terminals.

Single-source energy harvesting technologies often depend on the stability of the environment. For a complex and highly dynamic application environment in an Internet of Things scenario such as a smart home, the applicability of single-source energy harvesting technologies is greatly limited. The hybrid harvesting of three types of energy, i.e., solar energy, thermal energy, and mechanical energy that exist in nature is of great significance to passive autonomous, reliable, and stable operation of smart terminals in a complex and changing environment.

Photovoltaic cells use the photovoltaic effect to convert solar energy to electrical energy. In this process, about 80% or more of the solar energy is lost as heat. The heat not only leads to an increase in the temperature of the cell, but also reduces the output voltage and power, leading to a decrease in the conversion efficiency of the photovoltaic cell. For each 10° C. increase in temperature, the power generation efficiency decreases by about 0.5%. The high temperature and heat of the photovoltaic cell create a condition for reciprocally coupled energy harvesting of solar energy and thermal energy. A thermoelectric generator (TEG) uses the Seebeck effect to convert thermal energy to electrical energy, and a photovoltaic cell is used as a heat source of the TEG, so that solar energy and thermal energy can be harvested and utilized at the same time. In a stable heating environment, temperatures at tow ends of the TEG tend to be the same, and thermal energy cannot be continuously harvested. Therefore, a reliable heat dissipation mechanism needs to be provided to achieve a stable temperature difference to ensure conversion of thermal energy to electrical energy. The vibration characteristic of mechanical energy harvesting structures creates a condition for reciprocally coupled energy harvesting of mechanical energy and thermal energy. A piezoelectric material uses the piezoelectric effect to harvest energy generated by mechanical vibration and convert the mechanical energy to electrical energy. The air flow generated during vibration of a piezoelectric cantilever can dissipate heat for the TEG, so that a heat dissipation requirement for thermoelectric conversion can be met while harvesting mechanical energy.

### SUMMARY

Accordingly, the present disclosure provides a photoelectric-thermoelectric-piezoelectric coupled hybrid energy harvesting apparatus, for hybrid harvesting of three types of energy, i.e., solar energy, thermal energy, and mechanical energy that exist in nature, to maximize energy utilization.

A photoelectric-thermoelectric-piezoelectric coupled hybrid energy harvesting apparatus is provided, including a housing, a photoelectric-thermoelectric energy harvesting apparatus, and a piezoelectric energy harvesting apparatus,
where the housing is configured to support and accommodate the photoelectric-thermoelectric energy harvesting apparatus and the piezoelectric energy harvesting apparatus; the housing is a hexahedron, and the photoelectric-thermoelectric energy harvesting apparatus is respectively arranged on five surfaces of the housing to implement reciprocally coupled harvesting of solar energy and thermal energy in an environment; and the piezoelectric energy harvesting apparatus is arranged in an interior of the housing to implement reciprocally coupled harvesting of the thermal energy and mechanical energy in the environment.

Further, the photoelectric-thermoelectric-piezoelectric coupled hybrid energy harvesting apparatus further includes a heat dissipation plate provided with a heat dissipation hole and arranged on a surface of one side of the housing.

Preferably, the photoelectric-thermoelectric energy harvesting apparatus includes a photovoltaic cell panel, a first thermally conductive layer, a TEG, a second thermally conductive layer, and a heat dissipation sheet laminated in sequence.

Preferably, one side of the heat dissipation sheet is a smooth surface fitting to a rear portion of the second thermally conductive layer, and heat dissipation particles are distributed on a surface of an other side of the heat dissipation sheet.

Preferably, the photovoltaic cell panel is a single photovoltaic cell, or an array formed by a plurality of photovoltaic cells connected in series and parallel.

Preferably, the piezoelectric energy harvesting apparatus includes a vibration blade, an upper piezoelectric sheet, a lower piezoelectric sheet, a vibration blade mass, and a fixed end,
where the vibration blade is fixed to the fixed end, the upper piezoelectric sheet is arranged on an upper side of the vibration blade, the lower piezoelectric sheet is arranged on a lower side of the vibration blade, and the vibration blade mass is arranged at a front end of the vibration blade;
a voltage stabilization module and a power supply module are arranged inside the fixed end; and the voltage stabilization module is configured to perform voltage stabilization processing on electrical energy with different characteristics from the photoelectric-thermoelectric energy harvesting apparatus and the piezoelectric energy harvesting apparatus, and output stable electrical energy to the power supply module.

Preferably, the front end of the vibration blade is wide, a rear end of the vibration blade is narrow and long, and the rear end is connected to the fixed end.

Preferably, the vibration blade is made of a flexible material; and the upper piezoelectric sheet and the lower piezoelectric sheet are arranged symmetrically on the upper side and the lower side of the vibration blade.

Preferably, the fixed end of the piezoelectric energy harvesting apparatus is arranged at a center of a right side surface of the interior of the housing.

The present disclosure has the following advantages.
(1) The present disclosure makes full use of the reciprocal coupling relationship between energy harvesting mechanisms to skillfully design a photoelectric, thermoelectric, and piezoelectric power generation structure. With the use of the photoelectric-thermoelectric-piezoelectric coupled hybrid energy harvesting apparatus, reciprocal harvesting of solar energy, thermal energy, and mechanical energy that widely exist in nature can be realized, thereby breaking through the simple “1+1” implementation mode of multi-source energy harvesting.
(2) The apparatus of the present disclosure has a simple structure and is easy to implement. The electrical energy generated can be supplied to various electrical facilities such as Internet of Things nodes, so the apparatus of the present disclosure can be used in a wide range of applications. In addition, the apparatus of the present disclosure avoids the disadvantages of using a single-source energy harvesting technology in a complex and highly dynamic application environment, and is of great significance to the reliable and stable operation of the electrical facilities.

### BRIEF DESCRIPTION OF THE DRAWINGS

FIG. 1 is a structural diagram of a photoelectric-thermoelectric-piezoelectric coupled hybrid energy harvesting apparatus.

FIG. 2 is a structural diagram of a piezoelectric energy harvesting apparatus.

FIG. 3 is a structural diagram of a photoelectric-thermoelectric energy harvesting apparatus.

FIG. 4 is a flowchart of the apparatus of the present disclosure.

In the drawings: 1—housing, 2—piezoelectric energy harvesting apparatus, 3—heat dissipation plate, 401—upper photoelectric—thermoelectric energy harvesting apparatus, 402—right photoelectric—thermoelectric energy harvesting apparatus, 403—front photoelectric—thermoelectric energy harvesting apparatus, 404—left photoelectric—thermoelectric energy harvesting apparatus, 405—rear photoelectric—thermoelectric energy harvesting apparatus, 5—vibration blade, 601—upper piezoelectric sheet, 602—lower piezoelectric sheet, 7—vibration blade mass, 8—fixed end of piezoelectric energy harvesting apparatus, 9—photovoltaic cell panel, 10—first thermally conductive layer, 11—TEG, 12—second thermally conductive layer, and 13—heat dissipation sheet.

### DETAILED DESCRIPTION OF THE EMBODIMENTS

The present disclosure will be described in detail below with reference to the accompanying drawings.

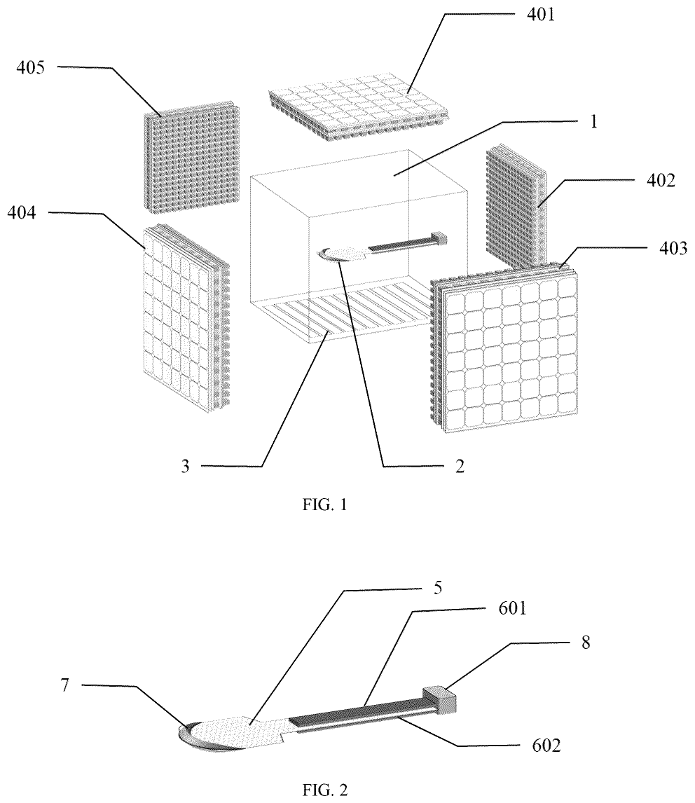

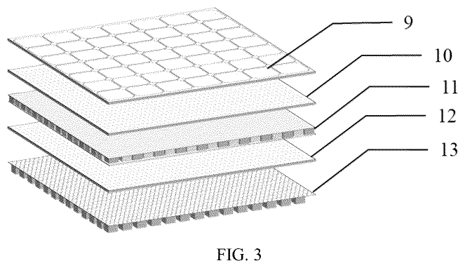

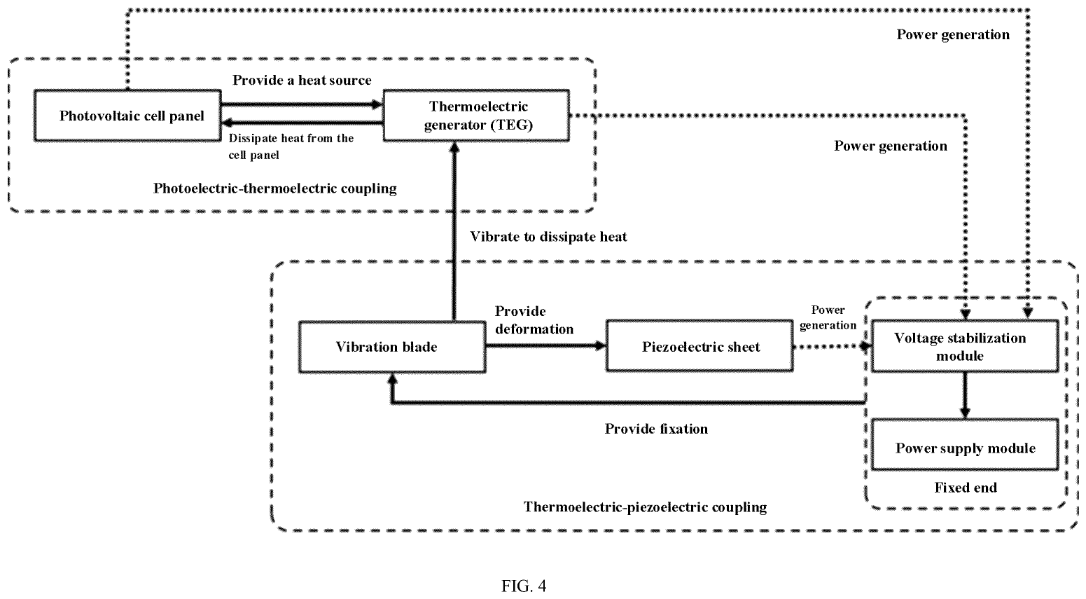

FIG. 1 shows a structure of a photoelectric-thermoelectric-piezoelectric coupled hybrid energy harvesting apparatus according to an embodiment. FIG. 2 shows a structure of a piezoelectric energy harvesting apparatus according to the embodiment. FIG. 3 shows a structure of a photoelectric-thermoelectric energy harvesting apparatus according to the embodiment. FIG. 4 is a flowchart according to the embodiment. The photoelectric-thermoelectric-piezoelectric coupled hybrid energy harvesting apparatus includes a housing 1, a piezoelectric energy harvesting apparatus 2, a heat dissipation plate 3, an upper photoelectric-thermoelectric energy harvesting apparatus 401, a right photoelectric-thermoelectric energy harvesting apparatus 402, a front left photoelectric-thermoelectric energy harvesting apparatus 403, a photoelectric-thermoelectric energy harvesting apparatus 404, a rear photoelectric-thermoelectric energy harvesting apparatus 405, a vibration blade 5, an upper piezoelectric sheet 601, a lower piezoelectric sheet 602, a vibration blade mass 7, a fixed end 8 of the piezoelectric energy harvesting apparatus, a photovoltaic cell panel 9, a first thermally conductive layer 10, a TEG 11, a second thermally conductive layer 12, a heat dissipation sheet 13, and necessary wires.

The apparatus of the present disclosure is configured for hybrid harvesting of three types of energy, i.e., solar energy, thermal energy, and mechanical energy that exist in nature, to maximize energy utilization. The apparatus mainly includes the housing 1, the photoelectric-thermoelectric energy harvesting apparatuses, and the piezoelectric energy harvesting apparatus 2.

The housing 1 is configured to support and accommodate the photoelectric-thermoelectric energy harvesting apparatus, the piezoelectric energy harvesting apparatus 2, and the heat dissipation plate 3. The housing 1 is of a hexahedral structure. The size of the housing may be designed based on actual requirements. The upper photoelectric-thermoelectric energy harvesting apparatus 401, the right photoelectric-thermoelectric energy harvesting apparatus 402, the front photoelectric-thermoelectric energy harvesting apparatus 403, the left photoelectric-thermoelectric energy harvesting apparatus 404, and the rear photoelectric-thermoelectric energy harvesting apparatus 405 are respectively arranged on five surfaces of the housing 1. The photoelectric-thermoelectric energy harvesting apparatuses are configured to implement reciprocally coupled harvesting of solar energy and thermal energy in a working environment. The piezoelectric energy harvesting apparatus 2 is arranged on a right side surface of an interior of the housing 1 to implement reciprocally coupled harvesting of thermal energy and mechanical energy by the apparatus in the working environment. The heat dissipation plate 3 is arranged on a surface of a lower side of the housing 1, and is provided thereon with a heat dissipation hole.

The photoelectric-thermoelectric energy harvesting apparatuses in the apparatus of the present disclosure have the same structure. As shown in FIG. 3, the photoelectric-thermoelectric energy harvesting apparatus includes the photovoltaic cell panel 9, the first thermally conductive layer 10, the TEG 11, the second thermally conductive layer 12, and the heat dissipation sheet 13 closely laminated together. The five parts have the same surface area, to reduce waste of heat.

In the photoelectric-thermoelectric energy harvesting apparatus, the photovoltaic cell panel 9 faces an exterior of the housing 1, and is configured to harvest solar energy and convert the solar energy to electrical energy. The photovoltaic cell panel 9 may be a single photovoltaic cell, or an array formed by a plurality of photovoltaic cells connected in series and parallel.

The first thermally conductive layer 10 is arranged on a rear portion of the photovoltaic cell panel 9, and is adhered to the rear portion of the photovoltaic cell panel 9 and a hot end of the TEG 11. The first thermally conductive layer 10 has a large coefficient of thermal conductivity. A clearance between a surface of the rear portion of the photovoltaic cell panel 9 and a surface of the hot end of the TEG 11 may be filled with a thermally conductive silicon grease or a double-sided adhesive tape HF-S43 for enhancing the thermal conductivity of the contact surface, to reduce the thermal contact resistance between the interfaces. The temperature of the photovoltaic cell panel 9 is transferred to the hot end of the TEG 11. The photovoltaic cell panel 9 serves as a heat source of the TEG 11, so that thermal energy can be harvested and converted to electrical energy. In addition, the TEG 11 serves as a heat conducting path for heat dissipation and cooling of the photovoltaic cell panel, to achieve reciprocally coupled harvesting of solar energy and thermal energy.

In the photoelectric-thermoelectric energy harvesting apparatus, the heat dissipation sheet 13 faces the interior of the housing 1, and is configured to dissipate heat. Table 1 shows coefficients of thermal conductivity of commonly used solid materials. Pure silver has good thermal conductivity, but is expensive. Pure copper has high thermal conductivity. Therefore, the heat dissipation sheet 13 is made of copper to improve the thermal conductivity. A surface of one side of the heat dissipation sheet 13 is smooth to improve the heat conduction effect, and a large number of heat dissipation particles are distributed on a surface of an other side of the heat dissipation sheet 13 to increase the surface area for heat dissipation.

TABLE 1
Coefficients of thermal conductivity of commonly used solid materials

| | Coefficient of | | Coefficient of |
|---|---|---|---|
| | thermal | | thermal |
| | conductivity | | conductivity |
| Solid material | (W/mK) | Solid material | (W/mK) |
| Pure silver | 429 | Aluminum alloy | 160 |
| | | 6061 | |
| Pure copper | 401 | Aluminum alloy | 201 |
| | | 6063 | |
| Bronze | 32-153 | Aluminum alloy | 130 |
| | | 7075 | |
| Pure aluminum | 237 | Aluminum alloy | 226 |
| | | 1070 | |
| Steel | 36-54 | Rigid PVC | 0.17 |

The second thermally conductive layer 12 is arranged on a rear portion of the heat dissipation sheet 13, and is adhered to a cold end of the TEG 11 and the heat dissipation sheet 13. The second thermally conductive layer 12 has a large coefficient of thermal conductivity. A clearance between a surface of the cold end of the TEG 11 and the smooth surface of the heat dissipation sheet 13 may be filled with a thermally conductive silicon grease or a double-sided adhesive tape HF-S43 for enhancing the thermal conductivity of the contact surface, to reduce the thermal contact resistance between the interfaces. The temperature of the cold end of the TEG 11 is transferred to the heat dissipation sheet 13 to improve the heat dissipation effect for the TEG 11, to provide a temperature difference and ensure continuous harvesting of thermal energy.

The piezoelectric energy harvesting apparatus 2 includes the vibration blade 5, the upper piezoelectric sheet 601, the lower piezoelectric sheet 602, the vibration blade mass 7, and the fixed end 8 of the piezoelectric energy harvesting apparatus.

The vibration blade 5 is fixed to the fixed end 8 of the piezoelectric energy harvesting apparatus. The upper piezoelectric sheet 601 is arranged on an upper side of the vibration blade. The lower piezoelectric sheet 602 is arranged on a lower side of the vibration blade. The vibration blade mass 7 is arranged at a front end of the vibration blade.

The front end of the vibration blade 5 is wide, a rear end of the vibration blade is narrow and long, and the rear end is connected to the fixed end 8 of the piezoelectric energy harvesting apparatus. The front end is free. The vibration blade mass 7 can increase the inertial mass of the vibration blade to adjust the vibration frequency and harvest more mechanical energy. The material of the vibration blade 5 is flexible, for example, a thin stainless steel material, and can vibrate and deform along with a displacement in the working environment. The upper piezoelectric sheet 601 and the lower piezoelectric sheet 602 are arranged symmetrically on the upper side and the lower side of the vibration blade 5, and are configured to deform along with the deformation of the vibration blade 5 to harvest mechanical energy and convert the mechanical energy to electrical energy.

The vibration of the vibration blade 5 accelerates the flow of air inside the housing to generate an air flow. The air flow improves the heat dissipation efficiency of the heat dissipation sheet 13, so that the temperature of the surface of the cold end of the TEG 11 is further reduced. In this way, a heat dissipation requirement for thermoelectric conversion is met while harvesting mechanical energy, thereby achieving reciprocally coupled harvesting of thermal energy and mechanical energy.

The fixed end 8 of the piezoelectric energy harvesting apparatus is arranged at a center of the right side surface of the interior of the housing 1. A pressure stabilization module and a power supply module are arranged inside the fixed end 8, to save space inside the housing, facilitate the flow of air inside the housing, and improve the heat dissipation effect. Electrical energy with different characteristics from the photoelectric-thermoelectric energy harvesting apparatuses and the piezoelectric energy harvesting apparatus is transmitted to the voltage stabilization module through the wires. The voltage stabilization module is configured to perform voltage stabilization processing on the electrical with different characteristics, and output stable electrical energy to the power supply module. The power supply module is configured to connect to a load and stably supply power to the load, and is further configured to store surplus electrical power generated by the photoelectric-thermoelectric-piezoelectric coupled hybrid energy harvesting apparatus.

The foregoing descriptions made with reference to the accompanying drawings are merely embodiments of the present disclosure and are not intended to limit the protection scope of the present disclosure. Any modifications, equivalent substitutions and improvements made within the concept and principle of the present disclosure shall fall within the scope of the present disclosure.

1. A photoelectric-thermoelectric-piezoelectric coupled hybrid energy harvesting apparatus, comprising a housing, a photoelectric-thermoelectric energy harvesting apparatus, and a piezoelectric energy harvesting apparatus, wherein
the housing is configured to support and accommodate the photoelectric-thermoelectric energy harvesting apparatus and the piezoelectric energy harvesting apparatus; the housing is a hexahedron, and the photoelectric-thermoelectric energy harvesting apparatus is respectively arranged on five surfaces of the housing to implement reciprocally coupled harvesting of solar energy and thermal energy in an environment; and the piezoelectric energy harvesting apparatus is arranged in an interior of the housing to implement reciprocally coupled harvesting of the thermal energy and mechanical energy in the environment.

2. The photoelectric-thermoelectric-piezoelectric coupled hybrid energy harvesting apparatus according to claim 1, further comprising a heat dissipation plate, wherein the heat dissipation plate is provided with a heat dissipation hole and arranged on a surface of a side of the housing.

3. The photoelectric-thermoelectric-piezoelectric coupled hybrid energy harvesting apparatus according to claim 1, wherein the photoelectric-thermoelectric energy harvesting apparatus comprises a photovoltaic cell panel, a first thermally conductive layer, a thermoelectric generator (TEG), a second thermally conductive layer, and a heat dissipation sheet laminated in sequence.

4. The photoelectric-thermoelectric-piezoelectric coupled hybrid energy harvesting apparatus according to claim 3, wherein a first side of the heat dissipation sheet is a smooth surface fitting to a rear portion of the second thermally conductive layer, and heat dissipation particles are distributed on a surface of a second side of the heat dissipation sheet.

5. The photoelectric-thermoelectric-piezoelectric coupled hybrid energy harvesting apparatus according to claim 3, wherein the photovoltaic cell panel is a single photovoltaic cell, or an array formed by a plurality of photovoltaic cells connected in series and parallel.

6. The photoelectric-thermoelectric-piezoelectric coupled hybrid energy harvesting apparatus according to claim 1, wherein the piezoelectric energy harvesting apparatus comprises a vibration blade, an upper piezoelectric sheet, a lower piezoelectric sheet, a vibration blade mass, and a fixed end;
wherein the vibration blade is fixed to the fixed end, the upper piezoelectric sheet is arranged on an upper side of the vibration blade, the lower piezoelectric sheet is arranged on a lower side of the vibration blade, and the vibration blade mass is arranged at a front end of the vibration blade; and
a voltage stabilization module and a power supply module are arranged inside the fixed end; and the voltage stabilization module is configured to perform voltage stabilization processing on electrical energy with different characteristics from the photoelectric-thermoelectric energy harvesting apparatus and the piezoelectric energy harvesting apparatus, and output stable electrical energy to the power supply module.

7. The photoelectric-thermoelectric-piezoelectric coupled hybrid energy harvesting apparatus according to claim 6, wherein the front end of the vibration blade is wide, a rear end of the vibration blade is narrow and long, and the rear end is connected to the fixed end.

8. The photoelectric-thermoelectric-piezoelectric coupled hybrid energy harvesting apparatus according to claim 6, wherein the vibration blade is made of a flexible material; and the upper piezoelectric sheet and the lower piezoelectric sheet are arranged symmetrically on the upper side and the lower side of the vibration blade.

9. The photoelectric-thermoelectric-piezoelectric coupled hybrid energy harvesting apparatus according to claim 6, wherein the fixed end of the piezoelectric energy harvesting apparatus is arranged at a center of a right side surface of the interior of the housing.

10. The photoelectric-thermoelectric-piezoelectric coupled hybrid energy harvesting apparatus according to claim 2, wherein the photoelectric-thermoelectric energy harvesting apparatus comprises a photovoltaic cell panel, a first thermally conductive layer, a TEG, a second thermally conductive layer, and a heat dissipation sheet laminated in sequence.

11. The photoelectric-thermoelectric-piezoelectric coupled hybrid energy harvesting apparatus according to claim 10, wherein a first side of the heat dissipation sheet is a smooth surface fitting to a rear portion of the second thermally conductive layer, and heat dissipation particles are distributed on a surface of a second side of the heat dissipation sheet.

12. The photoelectric-thermoelectric-piezoelectric coupled hybrid energy harvesting apparatus according to claim 10, wherein the photovoltaic cell panel is a single photovoltaic cell, or an array formed by a plurality of photovoltaic cells connected in series and parallel.
